(19) United States
(12) Patent Application Publication
(10) Pub. No.: US 2007/0171950 A1
(43) Pub. Date: Jul. 26, 2007

(54) SEMICONDUCTOR LASER DEVICE WITH SMALL VARIATION OF THE OSCILLATION WAVELENGTH

(75) Inventors: Kazuhisa TAKAGI, Tokyo (JP); Takeshi YAMATOYA, Tokyo (JP); Chikara WATATANI, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 11/469,501

(22) Filed: Sep. 1, 2006

(30) Foreign Application Priority Data
Jan. 25, 2006 (JP) 2006-015860

(51) Int. Cl. H01S 5/00

(52) U.S. Cl. 372/50.11

(57) ABSTRACT

A semiconductor laser has a structure in which the following layers are stacked on one another over an n-type substrate: a buffer layer, a diffraction grating layer, a diffraction grating burying layer, a light confining layer, a multiple quantum well active layer, a light confining layer, and a cladding layer. In this structure, the distance D between the center of the active layer and the interface between the n-type substrate and the buffer layer is set to a value longer than the 1/e²-beam spot radius a of the laser light.

### BACKGROUND OF THE INVENTION

1. Field of the Invention

The present invention relates to a semiconductor laser device, and more particularly to a semiconductor laser device used as a light source for optical communications systems or the like.

2. Background Art

Semiconductor laser devices have been widely used as light sources for optical communications systems, etc. For example, in “IPRM 2000 TuB6, pp. 55-56, Sudoh et al., Highly Reliable 1.3 μm InGaAlAs MQW DFB Lasers”, a semiconductor laser device employing an n-type InP substrate is disclosed.

In this semiconductor laser device, an n-InGaAsP diffraction grating layer is provided on the n-InP substrate. Further, the following layers are stacked to one another over the n-InGaAsP diffraction grating layer: an n-InP diffraction grating burying layer, an n-AlGaInAs light confining layer, an AlGaInAs multiple quantum well active layer, a p-AlGaInAs light confining layer, a p-InP cladding layer, a p-InGaAs contact layer, and a p-electrode.

The carrier concentration of the above substrate usually varies approximately between 1×10¹⁸ cm⁻³ and 4×10¹⁸ cm⁻³ due to manufacturing tolerances. This results in variations in the refractive index of the substrate due to plasma effect.

The intensity of the laser light within a semiconductor laser device is highest at the center portion of the active layer and decreases toward the substrate. Therefore, when the portion of the laser light reaches the substrate, the refractive index perceived by the laser light varies as the refractive index of the substrate changes.

For example, the higher the carrier concentration of the substrate, the lower the refractive index and hence the shorter the oscillation wavelength of the laser light. This results in an increase in the refractive index difference between the substrate and the diffraction grating layer and hence an increase in the coupling constant. Conversely, a reduction in the carrier concentration of the substrate leads to a decrease in the coupling constant.

That is, conventional semiconductor laser devices have a problem in that a change in the carrier concentration of the substrate results in an increased change in the oscillation wavelength of the laser light and in the coupling constant of the diffraction grating.

### SUMMARY OF THE INVENTION

The present invention has been developed to solve the above-described problems, and therefore it is an object of the present invention to provide a semiconductor laser device in which a change in the carrier concentration of the n-type semiconductor substrate results in only a small change in the oscillation wavelength of the laser light and in the coupling constant of the diffraction grating.

The above object is achieved by a semiconductor laser device that includes an n-type semiconductor substrate, a buffer layer provided on said semiconductor substrate and containing an n-type impurity, a diffraction grating layer provided on said buffer layer, and an active layer provided on said diffraction grating layer and generating laser light, and wherein, a distance D between the center of said active layer and the interface between said semiconductor substrate and said buffer layer is longer than a 1/e²-beam spot radius “a” of said laser light.

According to the present invention, it is possible to provide a semiconductor laser device in which a change in the carrier concentration of the n-type semiconductor substrate results in only a small change in the oscillation wavelength of the laser light and in the coupling constant of the diffraction grating.

Other features and advantages of the invention will be apparent from the following description taken in connection with the accompanying drawings.

### BRIEF DESCRIPTION OF DRAWINGS

FIG. 1 shows a cross-sectional view of a semiconductor laser;

FIG. 2 shows a cross-sectional view of a semiconductor laser of a ridge type structure;

FIG. 3 shows a cross-sectional view of a semiconductor laser of a buried hetero type structure; and

FIGS. 4 and 5 show the relationship between the thickness of the buffer layers and a beam spot radius of the laser light.

### DETAILED DESCRIPTION OF THE PREFERRED EMBODIMENTS

Embodiments of the present invention will be described below referring to the drawings. In the drawings, the same or equivalent parts will be denoted by the same reference numerals, and the description thereof will be simplified or omitted.

### First Embodiment

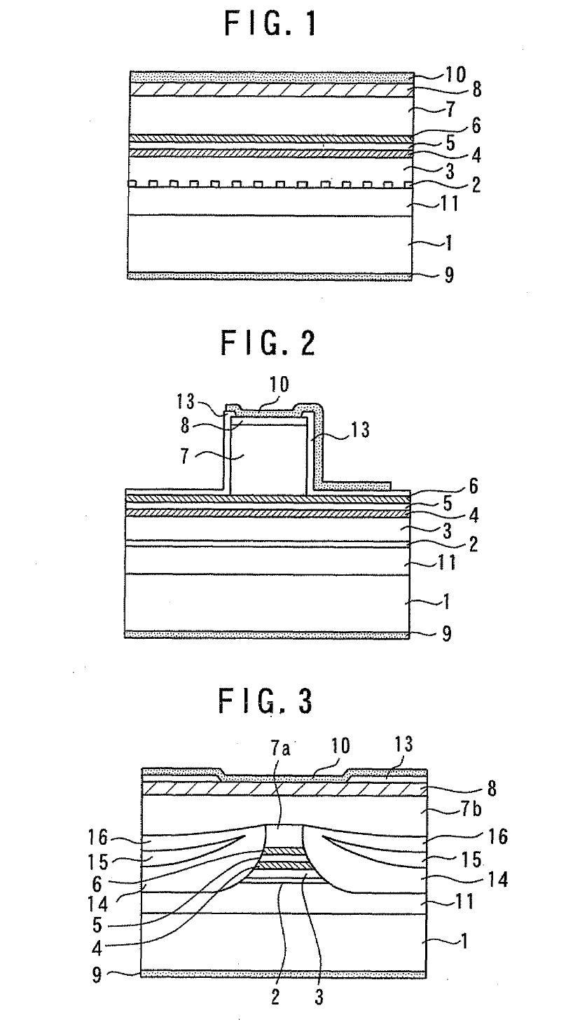

A semiconductor laser device according to a first embodiment of the present invention will be described. FIG. 1 is a cross-sectional view of the semiconductor laser device taken along a plane parallel to the direction of the resonator. This semiconductor laser device employs an n-type semiconductor substrate containing an n-type impurity such as Si, S, or Se. (“n-type” and “p-type” are hereinafter abbreviated as “n-” and “p-”, respectively.)

As shown in FIG. 1, an n-InP buffer layer 11 containing an n-type impurity is provided on an n-InP substrate 1. An n-InGaAsP diffraction grating layer 2 is provided on the n-InP buffer layer 11, and an n-InP diffraction grating burying layer 3 is provided on the n-InGaAsP diffraction grating layer 2. Further, an n-AlGaInAs light confining layer 4, an AlGaInAs multiple quantum well active layer 5, and a p-AlGaInAs light confining layer 6 are stacked over the n-InP diffraction grating burying layer 3. (The AlGaInAs multiple quantum well active layer is hereinafter referred to simply as the “active layer 5”.)

A p-InP cladding layer 7, a p-InGaAs contact layer 8, and p-side electrode 10 are provided over the p-AlGaInAs light confining layer 6. An n-side electrode 9 is provided on the back surface of the n-InP substrate 1. When the semiconductor laser is energized, holes are injected from the side of the p-InP cladding layer 7 into the active layer 5, and electrons are injected from the side of the n-InP diffraction grating burying layer 3 into the active layer 5. These holes and electrons are combined in the active layer 5 to generate laser light.

It should be noted that the n-InP buffer layer 11 is formed by metal organic chemical vapor deposition (MOCVD), molecular beam epitaxy (MBE), or liquid phase epitaxy (LPE). These techniques allow the impurity concentration of the n-InP buffer layer 11 to be highly controlled.

Further, the n-type impurity concentration of the n-InP buffer layer 11 varies about its mean value only within ±10% depending on the location within the buffer layer. This enables the refractive index of the n-InP buffer layer 11 to be stabilized.

FIG. 2 is a cross-sectional view of the emitting end of a ridge type semiconductor laser having a structure such as that shown in FIG. 1. In this structure, a ridge-shaped p-InP cladding layer 7 is provided on a p-AlGaInAs light confining layer 6, and a p-InGaAs contact layer 8 is provided on the ridge-shaped p-InP cladding layer 7. A silicon oxide film 13 is formed to cover the top surface of the p-AlGaInAs light confining layer 6 and the sides of the p-InP cladding layer 7 and the p-InGaAs contact layer 8. Further, a p-side electrode 10 is formed in contact with the top surface of the p-InGaAs contact layer 8.

FIG. 3 is a cross-sectional view of the emitting end of a buried heterostructure semiconductor laser having a structure such as that shown in FIG. 1. In this structure, the following layers are stacked to one another over an n-InP buffer layer 11: an n-InGaAsP diffraction grating layer 2, an n-InP diffraction grating burying layer 3, an n-AlGaInAs light confining layer 4, an active layer 5, a p-AlGaInAs light confining layer 6, and a first p-InP cladding layer 7a. These layers together form a film stack having a mesa shape. A p-InP current blocking layer 14, an n-InP current blocking layer 15, and a p-InP current blocking layer 16 are buried on both sides of this film stack. A second p-InP cladding layer 7b is stacked on the first p-InP cladding layer 7a and on the p-InP current blocking layer 16, and a p-InGaAs contact layer 8 is stacked on the second p-InP cladding layer 7b. Further, a silicon oxide film 13 is formed on the top surface of the p-InGaAs contact layer 8 so as to expose the central portion of the top surface of the p-InGaAs contact layer 8. Further, a p-side electrode 10 is formed to cover the exposed portion of the p-InGaAs contact layer 8.

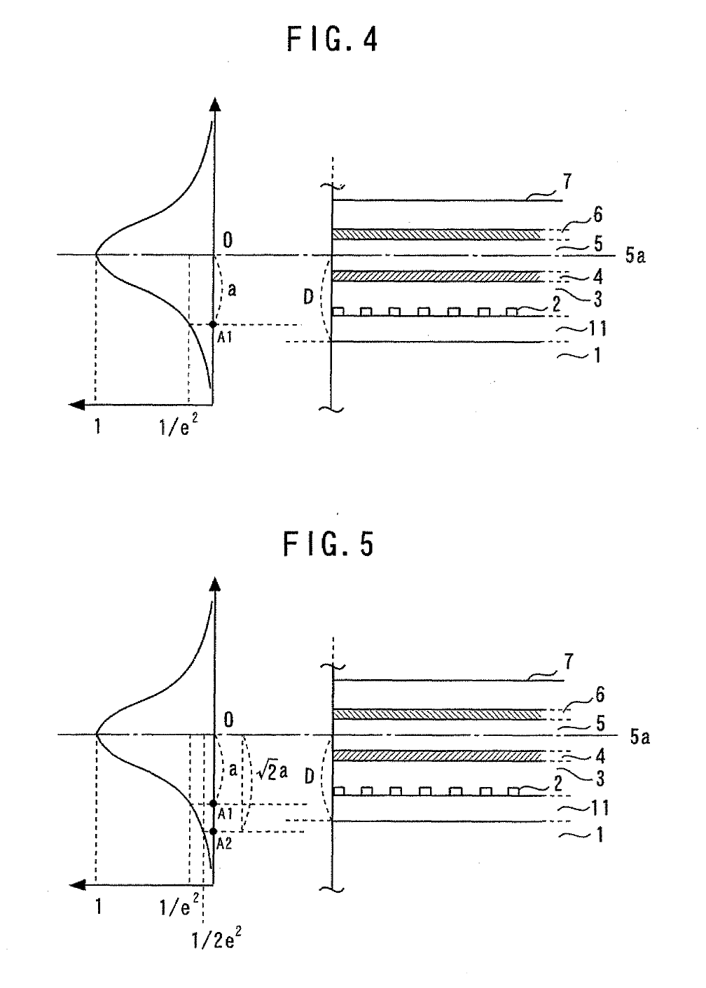

There will now be described the relationship between the thickness of the buffer layers 11 shown in FIGS. 1 to 3 and a beam spot radius of the laser light with reference to FIG. 4. In the graph shown on the left-hand side of FIG. 4, the vertical axis represents the distance from the central axis parallel to the laser light traveling direction (the central axis corresponding to the origin of the graph), and the horizontal axis represents the light intensity. The light intensity distribution is assumed to be gaussian with the highest light intensity at the center of the active layer 5.

Now, let the peak value of the intensity of the laser light be 1 and denote the point at which the light intensity is reduced to 1/e² by A1 (where e is the base of natural logarithms). Further, the distance “a” between the origin (i.e., the central axis) and the point A1 is defined as the “1/e²-beam spot radius of the laser light”.

In the cross-sectional structure shown on the right-hand side of FIG. 4, the laser light generated in the active layer 5 travels along the central 5a of the active layer 5. Therefore, the intensity of the laser light decreases from the center 5a toward the n-InP substrate 1 in accordance to the gaussian distribution. Now, let D denote the distance between the center 5a of the active layer 5 and the interface between the n-InP substrate 1 and the n-InP buffer layer 11.

According to the present embodiment, the distance D is set to a value longer than the 1/e²-beam spot radius “a” of the laser light. That is, the thickness of the n-InP buffer layer 11 is set such that a<D. With this arrangement, approximately 97.7% or more of the laser light generated in the active layer 5 is present in the layers above the interface between the n-InP substrate 1 and the n-InP buffer layer 11, and hence the amount of light leaking into the n-InP substrate 1 is approximately 2.3% or less. As a result, the laser light less perceive the variations in the refractive index of the n-InP substrate 1 due to variations in its carrier concentration caused by manufacturing tolerances of the substrate 1, as compared to conventional arrangements.

For example, assume that: the above beam spot radius “a” is 1 μm; the thickness of the active layer 5 is 0.1 μm; the thickness of the n-AlGaInAs light confining layer 4 is 0.2 μm; the thickness of the n-InP diffraction grating burying layer 3 is 0.1 μm; and the thickness of the n-InGaAsP diffraction grating layer 2 is 0.07 μm. In this case, when the thickness of the buffer layer is larger than 0.58 μm, the distance “D” is larger than 1 μm. Thus, the distance D can be set to a value greater than the beam spot radius “a”.

As described above, according to the present embodiment, the laser light less perceives the variations in the refractive index of the n-InP substrate 1 due to variations in its carrier concentration caused by manufacturing tolerances of the substrate, etc., as compared to conventional arrangements. Therefore, it is possible to reduce variations in the oscillation wavelength of the laser light and in the coupling constant of the diffraction grating.

### Second Embodiment

A semiconductor laser device according to a second embodiment of the present invention will be described with reference to FIG. 5 by focusing on the differences from the first embodiment.

A 1/e²-beam spot radius “a” of the laser light and a distance “D” are defined in the same way as in the first embodiment. Now, let A2 denote the point at which the intensity of the laser light is reduced to 1/(2*e²), as shown in FIG. 5 (where e is the base of natural logarithm). Then, since the laser light intensity distribution is gaussian, the distance between the origin (the central axis) and the point A2 is √2*a.

According to the present embodiment, the distance “D” is set to a value larger than the 1/e²-beam spot radius “a” of the laser light and smaller than √2*a. That is, the thickness of the n-InP buffer layer 11 is set such that a<D<√2*a. All other components are configured in the same way as in the first embodiment.

Since the distance “D” is within the above range, the amount of the light leaking into the n-InP substrate 1 is only approximately between 0.00003% and 2.3% of the total amount of light. As a result, it is possible to reduce variations in the oscillation wavelength of the laser light and in the coupling constant of the diffraction grating, as well as to improve uniformity of the characteristics of semiconductor laser devices in a manufacturing process.

For example, assume that the beam spot radius “a” and the thicknesses of the active layer 5, the n-AlGaInAs light confining layer 4, the n-InP diffraction grating burying layer 3, and the n-InGaAsP diffraction grating layer 2 are the same as those in the first embodiment. In such a case, when the thickness of the n-InP buffer layer 11 is between 0.58 μm and 1 μm, the relationship a<D<√2*a is satisfied. Thus, the distance “D” can be set within this range.

As described above, the present embodiment has the effect of improving uniformity of the characteristics of semiconductor laser devices in a manufacturing process, as well as the effects described in connection with the first embodiment.

It should be noted that in the first and second embodiments the n-InP diffraction grating burying layer 3 and the n-InP buffer layer 11 preferably contain the same element as their n-type impurities. For example, either Si or S may be used as the n-type impurities in these layers. This allows to suppress the interdiffusion of n-type impurities between the n-InP diffraction grating burying layer 3 and the n-InP buffer layer 11, resulting in stabilization of the refractive index of the n-InP buffer layer 11.

Further, in the first and second embodiments, the n-InP substrate 1 and the n-InP buffer layer 11 preferably contain the same element as their n-type impurities. For example, Si, S, or Se may be used as the n-type impurities in these layers. This allows a reduction in the interdiffusion of n-type impurities between the n-InP substrate 1 and the n-InP buffer layer 11, resulting in stabilization of the refractive index of the n-InP buffer layer 11. Therefore, it is possible to reduce the influence of the variations in the refractive index of the n-InP substrate 1 due to variations in its carrier concentration, allowing manufacture of a semiconductor laser having a stable oscillation wavelength and a stable coupling constant.

According to the first and second embodiments, the light confining layer 4, the active layer 5, and the light confining layer 6 are formed of AlGaInAs. However, these layers may be formed of InGaAsP instead of AlGaInAs, producing the same effect as the first and second embodiments.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2006-015860, filed on Jan. 25, 2006 including specification, claims, drawings and summary, on which the Convention priority of the present application is based, are incorporated herein by reference in its entirety.

1. A semiconductor laser device comprising:
an n-type semiconductor substrate;
a buffer layer on said semiconductor substrate and containing an n-type impurity;
a diffraction grating layer on said buffer layer; and
an active layer on said diffraction grating layer and generating laser light, wherein distance D between the center of said active layer and the interface between said semiconductor substrate and said buffer layer is longer than 1/e²-beam spot radius a of the laser light.

2. The semiconductor laser device according to claim 1, wherein the concentration of said n-type impurity contained in said buffer layer varies about a mean value within ±10% depending on location of said n-type impurity within said buffer layer.

3. The semiconductor laser device according to claim 1, wherein the distance D is smaller than √2*a.

4. The semiconductor laser device according to claim 1, wherein:
said semiconductor substrate is n-type InP; and
said semiconductor laser device has a ridge structure.

5. The semiconductor laser device according to claim 1, wherein:
said semiconductor substrate is n-type InP; and
said semiconductor laser device has a buried heterostructure.

6. The semiconductor laser device according to claim 1, wherein said buffer layer is formed using one of metal organic chemical vapor deposition, molecular beam epitaxy, and liquid phase epitaxy.

7. The semiconductor laser device according to claim 1, including a diffraction grating burying layer containing an n-type impurity located between said diffraction grating layer and said active layer, wherein said n-type impurities in said diffraction grating burying layer and in said buffer layer are the same element.

8. The semiconductor laser device according to claim 7, wherein said n-type impurities are one of Si and S.

9. The semiconductor laser device according to claim 1, wherein:
said semiconductor substrate contains an n-type impurity; and
said n-type impurities contained in said semiconductor substrate and in said buffer layer are the same element.

10. The semiconductor laser device according to claim 9, wherein said n-type impurities are selected from the group consisting of Si, S, and Se.
